(19) United States
(12) Patent Application Publication
(10) Pub. No.: US 2026/0314048 A1
(43) Pub. Date: Oct. 8, 2026

(54) INTEGRATED CIRCUIT DEVICE

(71) Applicant: SAMSUNG ELECTRONICS CO., LTD., Suwon-si (KR)

(72) Inventors: Soyeong AHN, Suwon-si (KR); Jihyung SEO, Suwon-si (KR); Suk YANG, Suwon-si (KR); Sangmoon LEE, Suwon-si (KR)

(73) Assignee: SAMSUNG ELECTRONICS CO., LTD., Suwon-si (KR)

(21) Appl. No.: 19/337,121

(22) Filed: Sep. 23, 2025

(30) Foreign Application Priority Data
Apr. 4, 2025 (KR) 10-2025-0044274

(51) Int. Cl. H10D 84/83; H10D 30/00; H10D 30/01; H10D 30/43; H10D 30/47; H10D 62/10; H10D 62/13; H10D 64/23; H10D 84/01

(52) U.S. Cl. CPC H10D 84/832; H10D 30/43; H10D 30/481; H10D 30/503; H10D 62/102; H10D 62/121; H10D 62/151; H10D 64/256; H10D 30/014; H10D 30/0191; H10D 84/0128

(57) ABSTRACT

Provided are an integrated circuit device and a method of manufacturing the same, wherein, in the integrated circuit device, a curved channel layer is arranged to improve electrical characteristics, and a gate insulating material is not formed in an inner spacer formed on sidewalls of a source/drain region, and thus parasitic capacitance is reduced.

### CROSS-REFERENCE TO RELATED APPLICATION

This application is based on and claims ranking under 35 U.S.C. § 119 to Korean Patent Application No. 10-2025-0044274, filed on Apr. 4, 2025, in the Korean Intellectual Property office, the disclosure of which is incorporated by reference herein in its entirety.

### BACKGROUND

The disclosure of this application relates to an integrated circuit device. More particularly, the disclosure relates to an integrated circuit device including a nanosheet field-effect transistor.

Due to the development of electronics technology, down-scaling of integrated circuit devices is rapidly progressing, and accordingly, it is necessary to maintain high operating speeds of integrated circuit devices and minimize leakage current to ensure operation accuracy. Various studies are being conducted to provide integrated circuit devices that have structures capable of reducing leakage current and improving electrical reliability.

### SUMMARY

The disclosure provides an integrated circuit device having a gate-all-around (GAA) structure including curved channels having transition metal dichalcogenides (TMD).

In addition, the issues to be solved by one or more of the technical ideas of the disclosure are not limited to those mentioned above, and other issues may be clearly understood by those of ordinary skill in the art from the following descriptions.

Provided is an integrated circuit device as follows:

According to one or more aspects of the disclosure, there is provided an integrated circuit device including an active region extending in a first horizontal direction on a substrate, a plurality of channel layers arranged apart from each other on the active region in a vertical direction, and extending in the first horizontal direction, oxide layers arranged under the plurality of channel layers, respectively, a gate line extending on the active region in a second horizontal direction crossing the first horizontal direction, and surrounding the plurality of channel layers and the oxide layers, a source/drain region arranged on the active region and in contact with the plurality of channel layers, and an inner spacer, wherein the inner spacer includes one sidewall in contact with a sidewall of the source/drain region, another sidewall opposite to the one sidewall and covering a sidewall of the gate line, and an upper surface and a lower surface each in contact with the plurality of channel layers, wherein the plurality of channel layers include a transition metal dichalcogenide (TMD) compound, and wherein each of the plurality of channel layers includes a plurality of convex curved units in the vertical direction.

According to one or more aspects of the disclosure, there is provided an integrated circuit device including an active region extending in a first horizontal direction on a substrate, a plurality of channel layers arranged apart from each other on the active region in a vertical direction, and extending in the first horizontal direction, a first oxide layer and a second oxide layer apart from each other with each of the plurality of channel layers therebetween, a gate line extending on the active region in a second horizontal direction crossing the first horizontal direction, and surrounding the plurality of channel layers, the first oxide layer, and the second oxide layer, a source/drain region arranged on the active region and in contact with the plurality of channel layers, and an inner spacer, wherein the inner spacer includes one sidewall in contact with a sidewall of the source/drain region, another sidewall opposite to the one sidewall and covering a sidewall of the gate line, and an upper surface and a lower surface each in contact with the plurality of channel layers, wherein the plurality of channel layers include a transition metal dichalcogenide (TMD) compound, and wherein each of the plurality of channel layers includes a plurality of convex curved units in the vertical direction.

According to one or more aspects of the disclosure, there is provided an integrated circuit device including an active region extending in a first horizontal direction on a substrate, a nanosheet stack including a plurality of nanosheets facing an upper surface of the active region at positions where the plurality of nanosheets are apart from the upper surface of the active region in a vertical direction, a gate line extending on the active region in a second horizontal direction crossing the first horizontal direction, and surrounding the plurality of nanosheets, the gate line including a sub-gate arranged between the plurality of nanosheets adjacent to each other in the vertical direction and between a nanosheet at a lowermost end and the active region, and covering the nanosheet at an uppermost end, a source/drain region in contact with the plurality of nanosheets, an insulating spacer covering sidewalls of the main gate, an inner spacer arranged between the sub-gate and the source/drain region, and a first oxide layer arranged between lower surfaces of the plurality of nanosheets and the gate line, wherein the first oxide layer is apart from the source/drain region by the inner spacer, and wherein the plurality of nanosheets include a transition metal dichalcogenide (TMD) compound, and upper surfaces and lower surfaces of the plurality of nanosheets include a plurality of convex uneven units in the vertical direction.

### BRIEF DESCRIPTION OF DRAWINGS

Embodiments will be more clearly understood from the following detailed description taken in conjunction with the accompanying drawings in which:

FIG. 1 is a layout of an integrated circuit device according to an embodiment;

FIG. 2A is a cross-sectional view of the integrated circuit device taken along line X1-X1′ in FIG. 1;

FIG. 2B is a cross-sectional view of the integrated circuit device taken along line Y1-Y1′ in FIG. 1;

FIG. 2C is a cross-sectional view of the integrated circuit device taken along line Y2-Y2′ in FIG. 1;

FIGS. 3 through 14 are cross-sectional views illustrating a method of manufacturing an integrated circuit device, according to embodiments; FIGS. 3, 4, 5, 6, 7, 8, 9, 10A, 11, 12, 13, and 14 are cross-sectional views of a region corresponding to a cross-section of an integrated circuit device taken along line X1-X1′ in FIG. 1 according to a respective process sequence, and FIG. 10B is a partially enlarged view of FIG. 10A;

FIGS. 15 through 17 are cross-sectional views illustrating a method of manufacturing an integrated circuit device, according to embodiments; and

FIG. 18 is another cross-sectional view of an integrated circuit device taken along line X1-X1′ in FIG. 1.

### DETAILED DESCRIPTION OF EMBODIMENTS

Hereinafter, embodiments of the disclosure are described in detail with reference to accompanying diagrams. Identical reference numerals are used for the same constituent devices in the drawings, and duplicate descriptions thereof are omitted.

Because various changes may be applied to the embodiments and the disclosure may have various embodiments, particular embodiments are illustrated in the diagrams and described in detail. However, this is not intended to limit the disclosure to particular modes of practice, and it is to be appreciated that all changes, equivalents, and substitutes, which do not depart from the spirit and technical scope of the disclosure, are encompassed in the disclosure. In the description of the embodiments, certain detailed explanations of the related art may be omitted when it is deemed that they may unnecessarily obscure the essence of the embodiments.

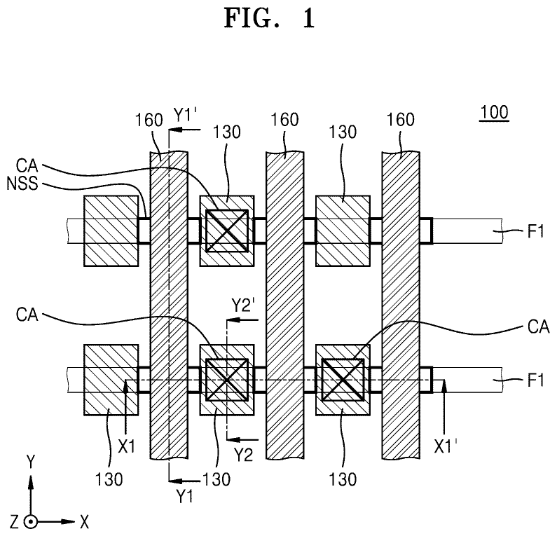

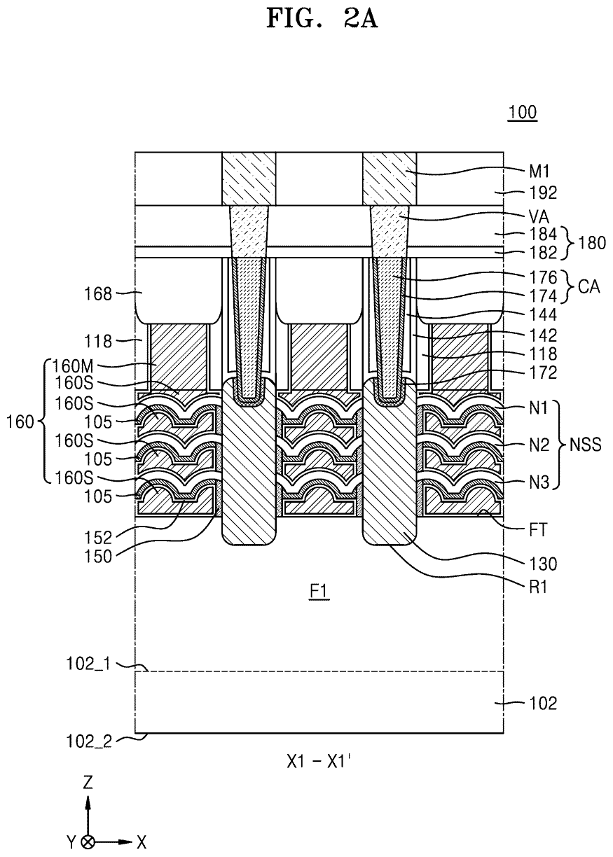

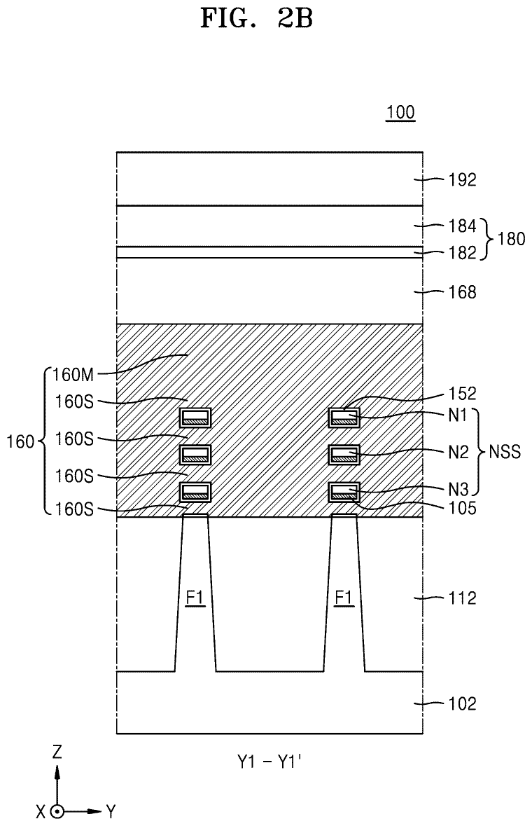

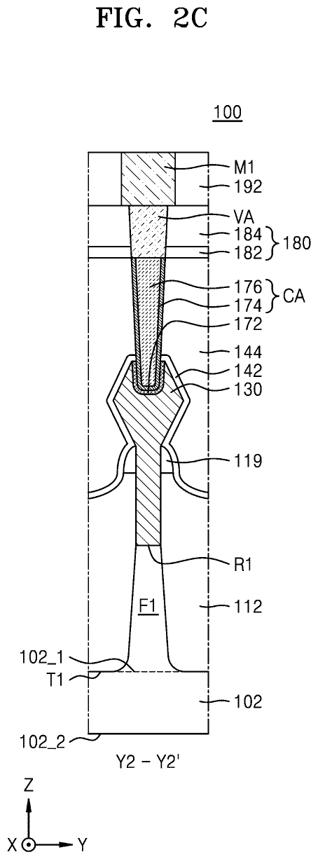

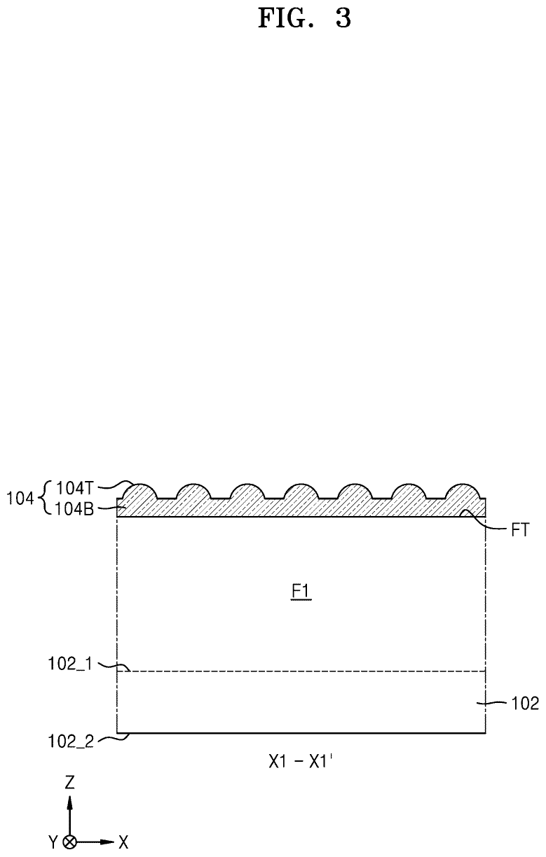

FIG. 1 is a layout of an integrated circuit device 100 according to an embodiment. FIG. 2A is a cross-sectional view of the integrated circuit device 100 taken along line X1-X1′ in FIG. 1. FIG. 2B is a cross-sectional view of the integrated circuit device 100 taken along line Y1-Y1′ in FIG. 1. FIG. 2C is a cross-sectional view of the integrated circuit device 100 taken along line Y2-Y2′ in FIG. 1.

Referring to FIGS. 1, 2A, 2B, and 2C, the integrated circuit device 100 according to the disclosure may mean an integrated circuit device including nanowires or nanosheet-shaped active regions, and having a gate-all-around (GAA) structure including gates surrounding the nanowires or nanosheet-shaped active regions. For example, the integrated circuit device 100 may include a multi bridge channel field-effect transistor (MBCFET) device. However, the disclosure is not limited thereto, and the integrated circuit device 100 may also include a planar field-effect transistor (FET) device, a fin FET (finFET) device, etc.

In some embodiments, the integrated circuit device 100 may include an active region F1 protruding from a substrate 102 to limit a trench region T1 on the substrate 102. A plurality of active regions F1 may extend in parallel with each other on the substrate 102 in the first horizontal direction (X direction), and may be arranged apart from each other in the second horizontal direction (Y direction).

In some embodiments, the integrated circuit device 100 may include an active region F1 protruding from a substrate 102 to limit a trench region T1 on the substrate 102.

In some embodiments, the substrate 102 may include a semiconductor, such as Si and Ge, or a compound semiconductor, such as SiGe, SiC, GaAs, InAs, InGaAs, and InP. The terms SiGe, SiC, GaAs, InAs, InGaAs, and InP used in the disclosure may be referred to as materials including elements included in each term, but may not be referred to as chemical formulas representing a stoichiometric relationship. The substrate 102 may include a conductive region comprising, for example, a well doped with impurities, or a structure doped with impurities.

In some embodiments, a device separation layer 112 may be arranged in the trench region T1 limiting the active region F1. The device separation layer 112 may cover portions of sidewalls of the active region F1 in the trench region T1, and may be apart from the substrate 102 in a vertical direction (Z direction). The device separation layer 112 may include a silicon oxide layer.

In some embodiments, a plurality of gate lines 160 may be arranged on the active region F1. Each of the plurality of gate lines 160 may extend long in the second horizontal direction (Y direction). A plurality of nanosheet stacks NSS may be arranged on a fin upper surface FT of the active region F1 in regions where the active region F1 crosses the plurality of gate lines 160. Each of the plurality of nanosheet stacks NSS may include at least one nanosheet facing the fin upper surface FT at a position apart from the fin upper surface FT of the active region F1 in the vertical direction (Z direction). The term “nanosheet” used in the disclosure may mean a conductive structure having a cross-section substantially perpendicular to a direction in which a current flows. The nanosheet should be understood as including nanowires.

In some embodiments, each of the plurality of nanosheet stacks NSS may include a plurality of nanosheet channel layers N1, N2, and N3 overlapping each other in the vertical direction (Z direction) on the active region F1. Vertical direction (Z direction) distances from the fin upper surface FT of the active region F1 to the plurality of nanosheet channel layers N1, N2, and N3 may be different from each other. Each of the plurality of gate lines 160 may surround the nanosheet channel layers N1, N2, and N3 included in the nanosheet stack NSS overlapping each other in the vertical direction (Z direction).

In FIG. 1, the nanosheet stack NSS has a roughly rectangular planar shape, but the embodiment is not limited thereto. The nanosheet stack NSS may have various planar shapes according to a planar shape of each of the active region F1 and the gate lines 160. In the embodiment, the plurality of nanosheet stacks NSS and the plurality of gate lines 160 may be arranged on one of the active regions F1, and a configuration is illustrated in which the plurality of nanosheet stacks NSS are arranged on one of the active regions F1 in a line in the first horizontal direction (X direction). However, the number of each of the nanosheet stacks NSS and the gate lines 160, which are arranged on the active regions F1, is not particularly limited.

In some embodiments, each of the plurality of nanosheet channel layers N1, N2, and N3 may have a thickness in a range of about 0.6 nm to about 3 nm, but is not limited thereto. For example, in some embodiments, the plurality of nanosheet channel layers N1, N2, and N3 may have a thickness of about 1.2 nm. In this case, the thickness of each of the plurality of nanosheet channel layers N1, N2, and N3 may mean a size in the vertical direction (Z direction). In some embodiments, the plurality of nanosheet channel layers N1, N2, and N3 may have substantially the same thickness in the vertical direction (Z direction). In some other embodiments, at least some of the plurality of nanosheet channel layers N1, N2, and N3 may have different thicknesses in the vertical direction (Z direction).

In some embodiments, the plurality of nanosheet channel layers N1, N2, and N3 included in one of the nanosheet stacks NSS may have the same or similar size in the first horizontal direction (X direction). In some other embodiments, unlike as illustrated in FIG. 2A, at least some of the plurality of nanosheet channel layers N1, N2, and N3 included in one of the nanosheet stacks NSS may have different sizes from each other in the first horizontal direction (X direction). In FIG. 2A, each of the plurality of nanosheet stacks NSS includes three nanosheet channel layers (for example, the first nanosheet channel layer N1, the second nanosheet channel layer N2, and the third nanosheet channel layer N3), but the disclosure is not limited thereto. For example, the nanosheet stack NSS may include at least one channel layer, and the number of channel layers constituting the nanosheet stack NSS is not particularly limited.

In some embodiments, the plurality of nanosheet channel layers N1, N2, and N3 may include a two-dimensional semiconductor material. In this case, the two-dimensional material may mean a material having a layered structure in which constituent atoms are two-dimensionally bonded. Two-dimensional materials having semiconductor characteristics have excellent electrical characteristics, and even when the thickness is reduced to a nano-scale, the characteristics thereof may not be significantly changed, and high mobility may be maintained. For example, the plurality of nanosheet channel layers N1, N2, and N3 may include transition metal dichalcogenides (TMD).

In some embodiments, the TMD may be a two-dimensional material having semiconductor characteristics and may be referred to as a compound of a transition metal and a chalcogen element. In this case, the transition metal may include at least one of, for example, Mo, W, Nb, V, Ta, Ti, Zr, Hf, Co, Tc, and Re, and the chalcogen element may include at least one of, for example, S, Se, and Te. The TMD may include MoS2, MoSe2, MoTe2, WS2, WSe2, WTe2, ZrS2, ZrSe2, HfS2, HfSe2, NbSe2, ReSe2, or the like, but the disclosure is not limited thereto.

In some embodiments, cross-sections of the plurality of nanosheet channel layers N1, N2, and N3 may have a curvature. Cross-sections of the plurality of nanosheet channel layers N1, N2, and N3 may have an arc shape or a semicircle shape that is convex upward. In this case, curvatures of the plurality of nanosheet channel layers N1, N2, and N3 may be uniform to each other as illustrated in FIG. 2A, but this is only an example. One or more of the curvatures of the plurality of nanosheet channel layers N1, N2, and N3 may also be different from each other, and the illustration of FIG. 2A does not limit the disclosure.

In some embodiments, a gate dielectric layer 152 may be arranged between the plurality of nanosheet channel layers N1, N2, and N3 and a gate line 160. The gate dielectric layer 152 may be formed at an interface between the plurality of nanosheet channel layers N1, N2, and N3 and the gate line 160. The gate dielectric layer 152 may be arranged between an oxide layer 105 and the gate line 160, which are formed on side surfaces, upper surfaces, and lower portions of the plurality of nanosheet channel layers N1, N2, and N3. The gate dielectric layer 152 may be formed to surround the plurality of nanosheet channel layers N1, N2, and N3 and the oxide layer 105. The gate dielectric layer 152 may be formed to surround the plurality of nanosheet channel layers N1, N2, and N3 and the oxide layer 105. For example, the gate dielectric layer 152 may cover the upper surfaces of the plurality of nanosheet channel layers N1, N2, and N3, a lower surface of the oxide layer 105, and sidewalls in the second horizontal direction (Y direction) of the plurality of nanosheet channel layers N1, N2, and N3 and the oxide layer 105, and may extend in the first horizontal direction (X direction).

In some embodiments, the plurality of nanosheet channel layers N1, N2, and N3 may have a monolayer or multilayer structure, wherein each layer may have an atomic level thickness.

In the case of an integrated circuit device according to a comparative example, an insulating layer may be arranged between a gate line and an inner spacer. On the other hand, in the integrated circuit device 100 of the disclosure, because a gate insulating material is not formed at the position where an inner spacer 150 is formed, parasitic capacitance may be reduced by reducing an area of an unnecessary insulating layer.

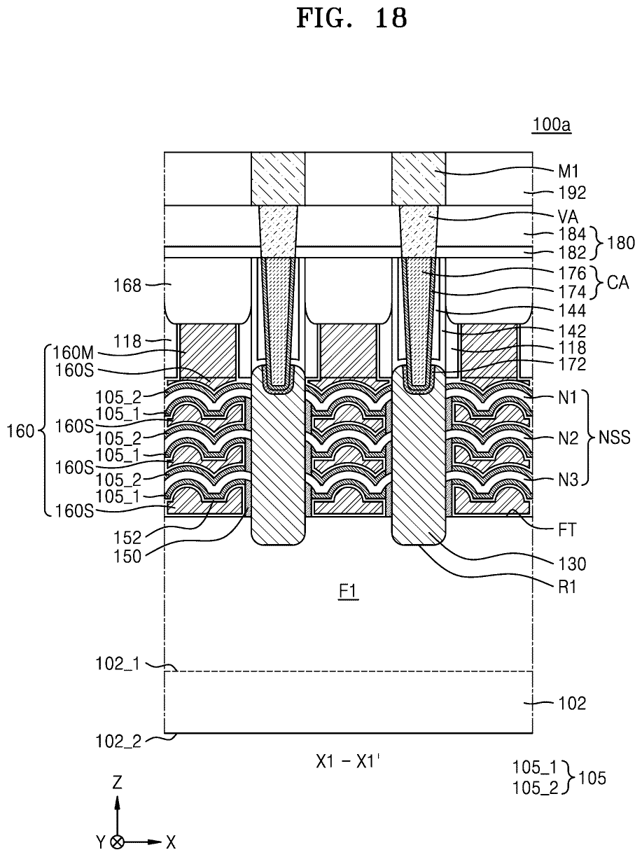

In some embodiments, the oxide layer 105 may be arranged between each of a plurality of sub-gates 160S and the plurality of nanosheet channel layers N1, N2, and N3. The oxide layer 105 may support the plurality of nanosheet channel layers N1, N2, and N3 under each of the plurality of nanosheet channel layers N1, N2, and N3. The oxide layer 105 may be formed to have a conformal thickness, and as the plurality of sub-gates 160S have a curved upper surface, the oxide layer 105 may also have a curved shape. FIG. 2A illustrates that the oxide layer 105 is arranged only under the plurality of nanosheet channel layers N1, N2, and N3, but the disclosure is not limited thereto. Referring to an integrated circuit device 100a of FIG. 18, the oxide layer 105 may be formed on both upper and lower portions of the plurality of nanosheet channel layers N1, N2, and N3. A first oxide layer 105_1 may be arranged under the plurality of nanosheet channel layers N1, N2, and N3, and a second oxide layer 105_2 may be arranged on the plurality of nanosheet channel layers N1, N2, and N3. Because the first and second oxide layers 105_1 and 105_2 may also be used as a gate dielectric layer, when both upper and lower portions of the sub-gate 160S are covered by the first and second oxide layers 105_1 and 105_2 as illustrated in FIG. 18, the gate dielectric layer 152 may be omitted.

In some embodiments, each of the plurality of gate lines 160 may include a main gate 160M and the plurality of sub-gates 160S. The main gate 160M may cover the upper surface of the nanosheet stack NSS, and extend in the second horizontal direction (Y direction). The plurality of sub-gates 160S may be connected to the main gate 160M in one body, and may be respectively arranged between each of the plurality of nanosheet channel layers N1, N2, and N3, and between the nanosheet channel layers N1, N2, and N3 arranged at the lowermost end and the active region F1. In the vertical direction (Z direction), a thickness of each of the plurality of sub-gates 160S may be less than a thickness of the main gate 160M.

In some embodiments, each of the plurality of gate lines 160 may include a metal, metal nitride, metal carbide, or a combination thereof. The metal may include one of Ti, W, Ru, Nb, Mo, Hf, Ni, Co, Pt, Yb, Tb, Dy, Er, and Pd. The metal nitride may include one of TiN and TaN. The metal carbide may include TiAlC. However, the materials constituting the plurality of gate lines 160 are not limited to the examples described above.

In some embodiments, a plurality of active region recesses R1 may be formed on the active region F1. A vertical level of the lowermost surface of each of the plurality of active region recesses R1 may be lower than a vertical level of the fin upper surface FT of the active region F1.

In some embodiments, a plurality of source/drain regions 130 may be arranged between each of the plurality of gate lines 160. Each of the plurality of source/drain regions 130 may be arranged at a position adjacent to at least one of the gate lines 160 among the plurality of gate lines 160. Each of the plurality of source/drain regions 130 may have surfaces facing the plurality of nanosheet channel layers N1, N2, and N3 adjacent thereto.

In some embodiments, each of the plurality of inner spacers 150 may be arranged between the plurality of sub-gates 160S and the plurality of source/drain regions 130. One sidewall of the inner spacer 150 may be in contact with the sub-gate 160S, and the other sidewall opposite to the one sidewall may be in contact with the source/drain region 130. In addition, each of the upper and lower surfaces of the inner spacer 150 may be in contact with the plurality of nanosheet channel layers N1, N2, and N3. A plurality of inner spacers 150 may cover sidewalls in the first horizontal direction (X direction) of the sub-gate 160S. A pair of inner spacers 150 may be apart from each other in the first horizontal direction (X direction) with the sub-gate 160S therebetween. In this case, the inner spacer 150 may include silicon nitride, silicon oxide, SiCN, SiBN, SiON, SiOCN, SiBCN, SiOC, or a combination thereof.

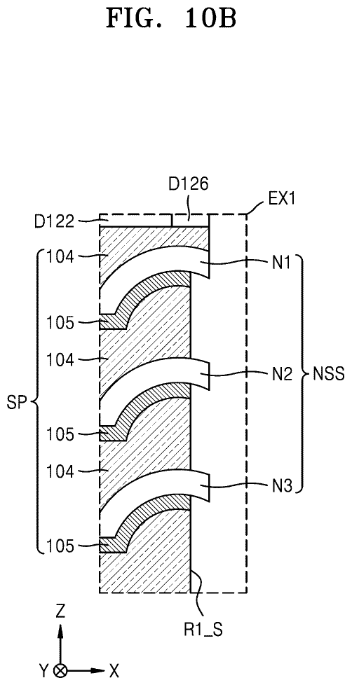

In some embodiments, some of the sidewalls of the plurality of source/drain regions 130 may be in contact with the inner spacer 150, and the other may be in contact with the plurality of nanosheet channel layers N1, N2, and N3. In other words, the plurality of source/drain regions 130 may not be in direct contact with the oxide layer 105. In some embodiments, not the oxide layer 105 but the inner spacer 150 may be arranged under the plurality of nanosheet channel layers N1, N2, and N3 in a region adjacent to the plurality of source/drain regions 130, which is a region where the inner spacer 150 is arranged. This may be a result of a process of removing a portion of the oxide layer 105 to form the inner spacer 150, as to be described below with reference to FIGS. 10A and 10B.

In some embodiments, each of the plurality of source/drain regions 130 may include an epitaxially grown semiconductor layer. In some embodiments, each of the plurality of source/drain regions 130 may include an epitaxially grown Si layer, an epitaxially grown SiC layer, or a plurality of epitaxially grown SiGe layers. When the source/drain region 130 includes an NMOS transistor, the source/drain region 130 may include an Si layer doped with n-type dopant or an SiC layer doped with n-type dopant. The n-type dopant may include phosphorus (P), arsenic (As), or antimony (Sb). When the source/drain region 130 includes an NMOS transistor, the source/drain region 130 may include an SiGe layer doped with n-type dopant. The p-type dopant may include boron (B) or gallium (Ga).

In some embodiments, the plurality of nanosheet stacks NSS may be arranged on the fin upper surface FT of each of a plurality of active regions F1 in regions where the plurality of active regions F1 intersect respectively the plurality of gate lines 160, and a plurality of FETs may be formed in regions where a plurality of active regions F1 respectively intersect the plurality of gate lines 160 on the substrate 102.

In some embodiments, a capping insulating pattern 168 may be arranged on the gate line 160. The capping insulating pattern 168 may cover an upper surface of the main gate 160M. The capping insulating pattern 168 may include a silicon nitride layer and a silicon oxide layer.

In some embodiments, both sidewalls of the main gate 160M may be covered with a first insulating spacer 118. The first insulating spacer 118 may be formed on both sidewalls of the main gate 160M on the upper surface of the plurality of nanosheet stacks NSS, and the capping insulating pattern 168 may be arranged on the first insulating spacer 118 and the gate line 160.

In some embodiments, a plurality of second insulating spacers 119 covering each of one sidewall of the source/drain region 130 and the other sidewall facing the one sidewall may be arranged on the upper surface of the device separation layer 112. In some embodiments, each of the plurality of second insulating spacers 119 may be connected to the first insulating spacer 118 adjacent thereto in one body. In some other embodiments, at least some of the plurality of second insulating spacers 119 may be omitted.

In some embodiments, each of the plurality of first insulating spacers 118 and the plurality of second insulating spacers 119 may include silicon nitride, silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC” used in the disclosure may be referred to as materials including elements included in each term, but may not be referred to as chemical formulas representing a stoichiometric relationship.

In some embodiments, a metal silicide layer 172 may be arranged on an upper surface of each of the plurality of source/drain regions 130. The metal silicide layer 172 may include a metal including Ti, W, Ru, Nb, Mo, Hf, Ni, Co, Pt, Yb, Tb, Dy, Er, or Pd. For example, the metal silicide layer 172 may include titanium silicide, but is not limited thereto.

In some embodiments, an insulating liner 142 and an inter-gate insulating layer 144 may be sequentially arranged on the plurality of source/drain regions 130 and a plurality of metal silicide layers 172. The first insulating spacer 118 and the plurality of source/drain regions 130 may be covered with the insulating liner 142. In some embodiments, the insulating liner 142 may include silicon nitride (SiN), SiCN, SiBN, SiON, SiOCN, SiBCN, or a combination thereof, but is not limited thereto. The inter-gate insulating layer 144 may include a silicon oxide layer, but is not limited thereto.

In some embodiments, a plurality of source/drain contacts CA may be respectively arranged on the plurality of source/drain regions 130. Each of the plurality of source/drain contacts CA may penetrate the insulating liner 142 and the inter-gate insulating layer 144 in the vertical direction (Z direction), and may be configured to be electrically connected to at least one source/drain region 130 among the plurality of source/drain regions 130. Each of the plurality of source/drain contacts CA may be in contact with the metal silicide layer 172 formed on the source/drain region 130. Each of the plurality of source/drain contacts CA may be configured to be electrically connected to the source/drain region 130 via the metal silicide layer 172. Each of the plurality of source/drain contacts CA may be apart from the main gate 160M of the gate line 160 with the first insulating spacer 118 therebetween in the first horizontal direction (X direction).

In some embodiments, each of the plurality of source/drain contacts CA may include a conductive barrier layer 174 and a contact plug 176. A lower surface and sidewalls of the contact plug 176 may be covered with the conductive barrier layer 174. The conductive barrier layer 174 may include a metal or conductive metal nitride. For example, the conductive barrier layer 174 may include Ti, Ta, W, TiN, TaN, WN, WCN, TiSiN, TaSiN, WSiN, or a combination thereof, but is not limited thereto. The contact plug 176 may include molybdenum (Mo), tungsten (W), cobalt (Co), ruthenium (Ru), manganese (Mn), titanium (Ti), tantalum (Ta), aluminum (Al), copper (Cu), or a combination thereof, or an alloy thereof, but is not limited thereto. In other embodiments, the conductive barrier layer 174 may be omitted from each of the plurality of source/drain contacts CA.

In some embodiments, an upper surface of each of the source/drain contact CA, the capping insulating pattern 168, the insulating liner 142, and the inter-gate insulating layer 144 may be covered by an upper insulating structure 180. The upper insulating structure 180 may include an etching stop layer 182 and an interlayer insulating layer 184, which are sequentially stacked on each of the plurality of source/drain contacts CA, a plurality of capping insulating patterns 168, and the inter-gate insulating layer 144. The etching stop layer 182 may include SiC, SiN, nitrogen-doped silicon carbide (SiC:N), SiOC, AlN, AlON, AlO, AlOC, or a combining thereof. The interlayer insulating layer 184 may include an oxide layer, a nitride layer, an ultra low-k (ULK) layer having an ultra low dielectric constant K of about 2.2 to about 2.4, or a combination thereof. For example, the interlayer insulating layer 184 may include a tetra-ethyl-ortho-silicate (TEOS) layer, a high density plasma (HDP) layer, a boro-phospho-silicate glass (BPSG) layer, a flowable chemical vapor deposition (FCVD) oxide layer, an SiON layer, an SiOC layer, an SiCOH layer, or a combination thereof, but is not limited thereto.

In some embodiments, a plurality of source/drain via contacts VA may be respectively arranged on the plurality of source/drain contacts CA. Each of the plurality of source/drain via contacts VA may penetrate the upper insulating structure 180 and be in contact with the source/drain contact CA. Each of the plurality of source/drain regions 130 may be configured to be electrically connected to the source/drain via contact VA via the metal silicide layer 172 and the source/drain contact CA. A lower surface of each of the plurality of source/drain via contacts VA may be in contact with an upper surface of the source/drain contact CA. Each of the plurality of source/drain via contacts VA may include Mo or W, but is not limited thereto.

In some embodiments, an upper surface of each of the upper insulating structure 180 and the plurality of source/drain via contacts VA may be covered by an upper insulating layer 192. The constituent material of the upper insulating layer 192 may be substantially the same as the constituent material of the interlayer insulating layer 184 described above.

In some embodiments, a plurality of upper wiring layers M1 may be arranged to penetrate the upper insulating layer 192. Each of the plurality of upper wiring layers M1 may be electrically connected to one source/drain via contact VA thereunder, selected from the plurality of source/drain via contacts VA. The plurality of upper wiring layers M1 may include Mo, Cu, W, Co, Ru, Mn, Ti, Ta, Al, a combination thereof, or an alloy thereof, but is not limited thereto.

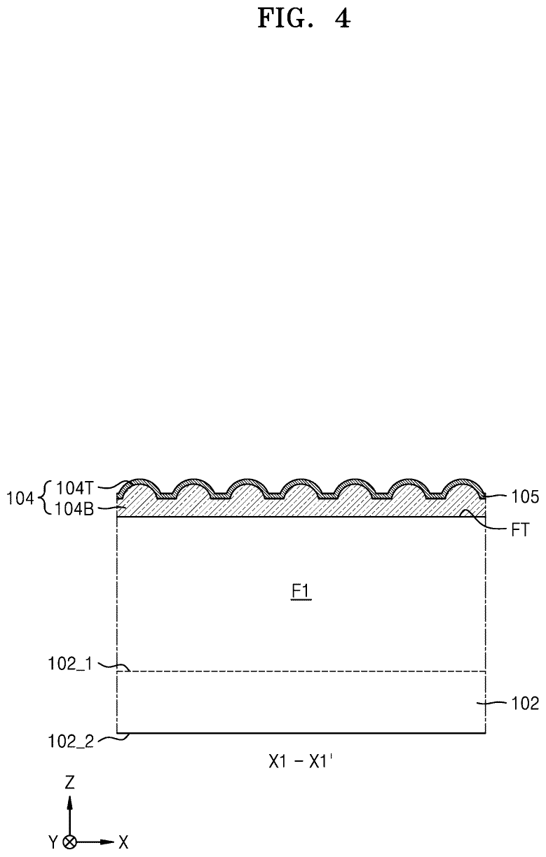

FIGS. 3 through 14 are cross-sectional views illustrating a method of manufacturing the integrated circuit device 100, according to embodiments. FIGS. 3, 4, 5, 6, 7, 8, 9, 10A, 11, 12, 13, and 14 are cross-sectional views of a region corresponding to a cross-section of the integrated circuit device 100 taken along line X1-X1′ in FIG. 1 according to a respective process sequence, and FIG. 10B is a partially enlarged view of FIG. 10A. Referring to FIGS. 3 through 14, an example method of manufacturing the integrated circuit device 100 described above with reference to FIGS. 1 through 2C is described. Hereinafter, the same reference numerals as in FIGS. 1 through 2C may denote the same members, and duplicate descriptions thereof are omitted.

Referring to FIG. 3, a sacrificial layer 104 may be formed on the substrate 102. The sacrificial layer 104 may include a bottom unit 104B and an upper surface unit 104T, and the bottom unit 104B and the upper surface unit 104T may include the same material. A lower surface of the sacrificial layer 104 may be formed to be flat while coplanar with the upper surface of the substrate 102, and an upper surface of the sacrificial layer 104 may include a plurality of convex portions. In other words, the upper surface unit 104T of the sacrificial layer 104 may not be parallel with the upper surface of the substrate 102, and may be formed in a curved shape.

The bottom unit 104B and the upper surface unit 104T of the sacrificial layer 104 may also be formed in one body, or sequentially formed. When the bottom unit 104B and the upper surface unit 104T of the sacrificial layer 104 are sequentially formed, the bottom unit 104B may be conformally formed at a certain thickness on the upper surface of the substrate 102, and then a plurality of nanocrystals may be arranged on the upper surface of the bottom unit 104B, and thereafter, the plurality of nanocrystals may be grown to form an upwardly convex protrusion unit on the bottom unit 104B. In this case, the size and/or density of the nanocrystal arranged on the bottom unit 104B may vary according to a user's setting, and thus the disclosure is not limited thereto. The bottom unit 104B and the upper surface unit 104T of the sacrificial layer 104 may include Si.

In some embodiments, the substrate 102 may include an element semiconductor, such as Si and Ge, or a compound semiconductor, such as SiGe, SiC, GaAs, InAs, InGaAs, and InP. The substrate 102 may include a first surface 102_1 and a second surface 102_2 opposite to the first surface 102_1. The plurality of active regions F1 may extend in the first horizontal direction (X direction) on the first surface 102_1 of the substrate 102. The sacrificial layer 104 may be arranged on the fin upper surface FT of each of the plurality of active regions F1.

Referring to FIG. 4, the oxide layer 105 may be formed on the resultant product of FIG. 3. In some embodiments, the oxide layer 105 may also be formed naturally, but may also be obtained by oxidizing the surface of the sacrificial layer 104. The oxide layer 105 may be formed on the upper surface of the sacrificial layer 104 at a conformal thickness, and as the upper surface unit 104T of the sacrificial layer 104 has a curved upper surface, the oxide layer 105 may also be deposited on the sacrificial layer 104 in a curved shape.

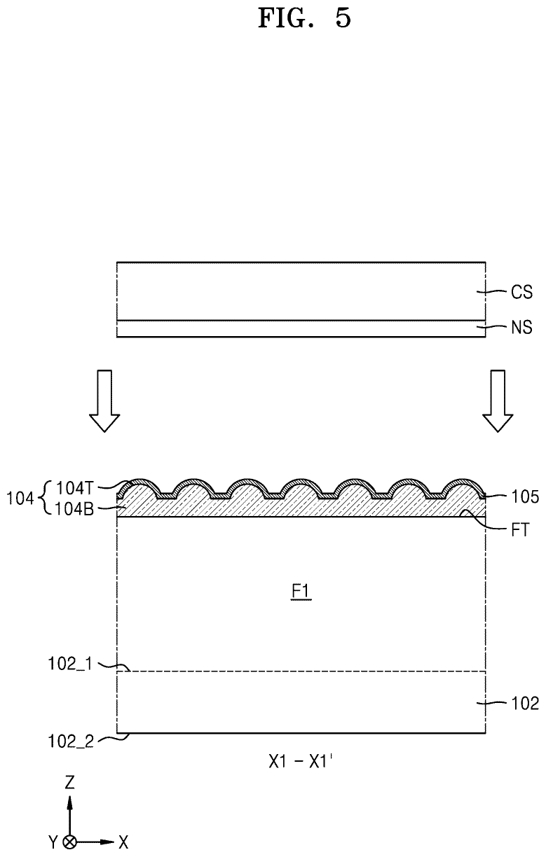

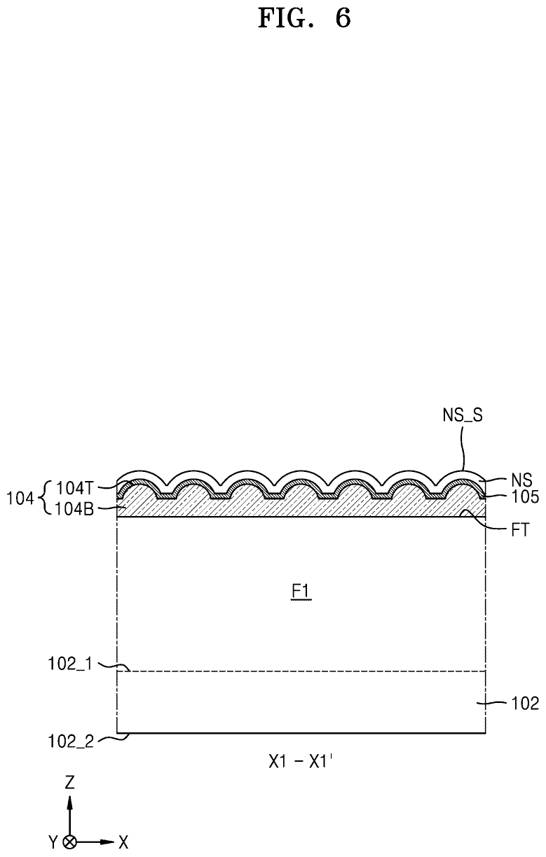

Referring to FIGS. 5 and 6, a nanosheet layer NS having a certain thickness may be formed on the oxide layer 105. In this case, the nanosheet layer NS may be transferred from a carrier substrate CS and attached onto the oxide layer 105.

After the nanosheet layer NS is formed on the carrier substrate CS, the carrier substrate CS may be flipped over so that the nanosheet layer NS faces the upper surface of the substrate 102, and the carrier substrate CS may be attached onto the substrate 102 (refer to FIG. 5). In this case, to attach the nanosheet layer NS onto the substrate 102, a process of applying heat and/or pressure may be additionally performed.

In some embodiments, the sacrificial layer 104 and the nanosheet layer NS may include semiconductor materials having different etching selectivity. In some embodiments, the nanosheet layer NS may include the TMD.

In some embodiments, the thickness in the vertical direction (Z direction) of the nanosheet layer NS may be about 1.2 nm. However, the embodiment is not limited thereto. For example, the thickness of the nanosheet layer NS may be in a range from about 0.6 mm to about 3 mm.

A type of the carrier substrate CS may not be limited, but the carrier substrate CS may include a flexible material. This may be because the oxide layer 105 has a curved shape, and accordingly, all surfaces of the oxide layer 105 may need to be in contact with the nanosheet layer NS of the carrier substrate CS in the process of attaching the carrier substrate CS onto the oxide layer 105. When the nanosheet layer NS is attached onto the oxide layer 105, the carrier substrate CS may be removed, and accordingly, as illustrated in FIG. 6, a curved nanosheet layer NS may be formed. An upper surface NS_S of the nanosheet layer NS may not be parallel with the upper surface of the substrate 102, and may have an upwardly convex shape like the upper surface unit 104T of the sacrificial layer 104. In some embodiments, the oxide layer 105 may support the nanosheet layer NS under the nanosheet layer NS.

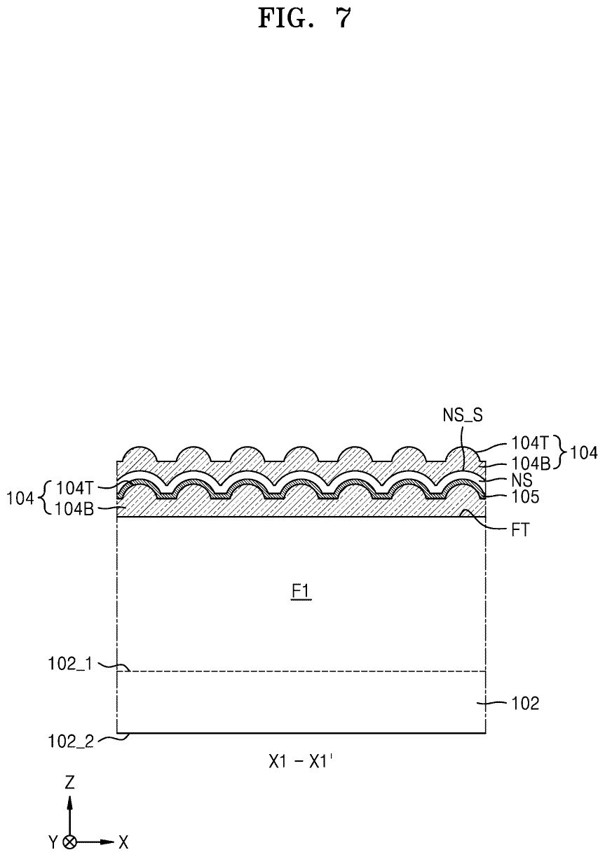

Referring to FIG. 7, the sacrificial layer 104 may be formed again on the nanosheet layer NS. The sacrificial layer 104 may include the bottom unit 104B and the upper surface unit 104T. As described with reference to FIG. 3, the bottom unit 104B and the upper surface unit 104T of the sacrificial layer 104 may be formed simultaneously or may be formed sequentially.

Although FIG. 7 illustrates that convex curved units of the sacrificial layers 104 apart from each other in the vertical direction (Z direction) with the nanosheet layer NS therebetween may comprise substantially identical curvatures, the embodiment is not limited thereto, and respective convex curved units may have different curvatures from each other.

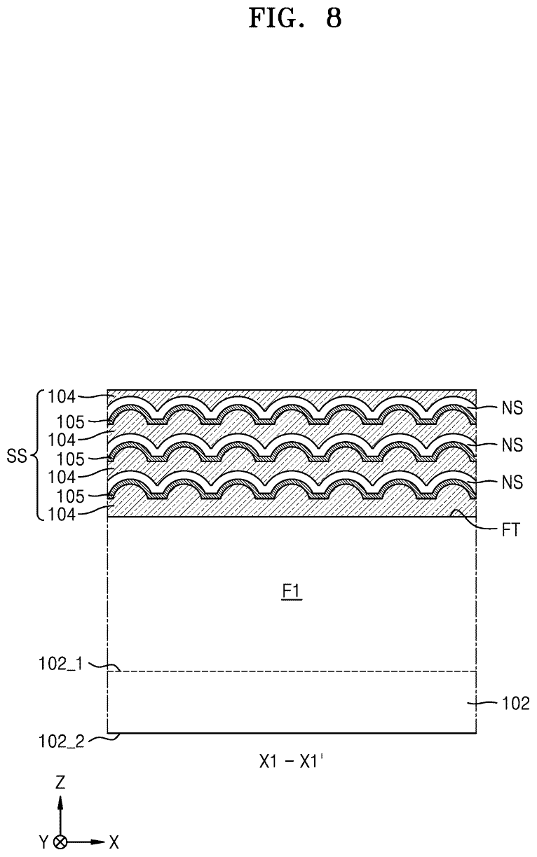

Referring to FIG. 8, the process described with reference to FIGS. 3 through 7 may be sequentially performed multiple times on the resultant product of FIG. 7, and a stacked structure SS in which a plurality of sacrificial layers 104, a plurality of oxide layers 105, and a plurality of nanosheet layers NS may be alternately stacked one by one. The plurality of nanosheet layers NS may have a monolayer structure or a multilayer structure. In FIG. 8, three of the nanosheet layers NS are included in the stacked structure SS, but this is only an example, and does not limit the disclosure.

In some embodiments, as illustrated in FIG. 8, the curved patterns of the upper and lower surfaces of the plurality of nanosheet layers NS may be the same. However, the embodiment is not limited thereto, and the curved patterns of the upper and lower surfaces of the plurality of nanosheet layers NS may be different from each other.

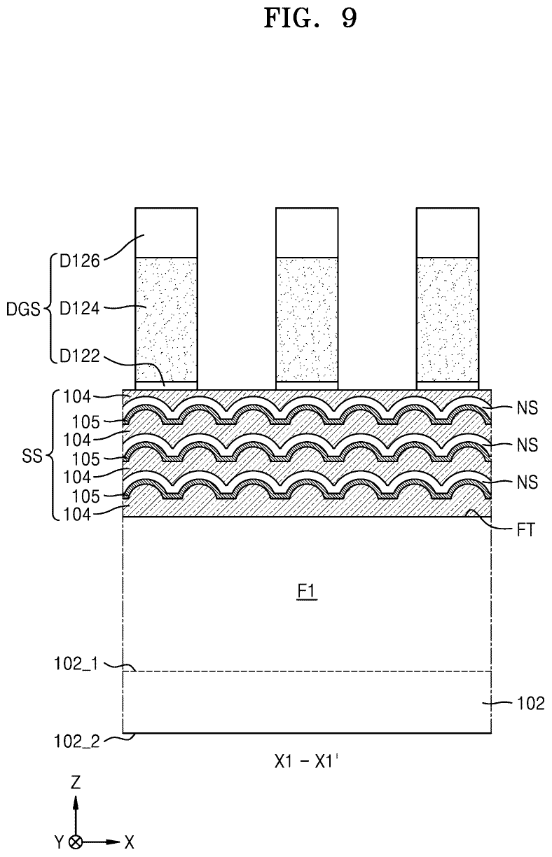

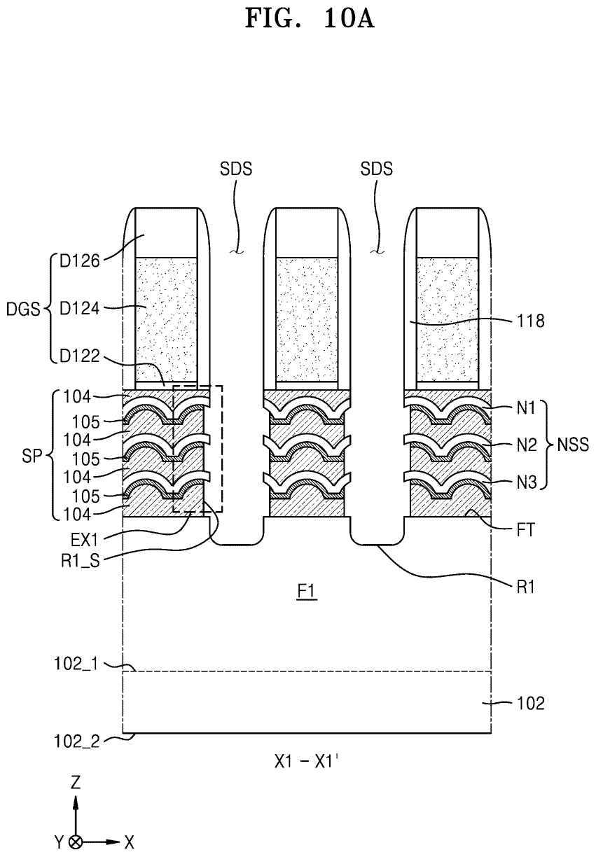

Referring to FIG. 9, a plurality of dummy gate structures DGS may be formed on the stacked structure SS of the plurality of sacrificial layers 104 and the plurality of nanosheet layers NS.

Each of the plurality of dummy gate structures DGS may be formed to extend in the second horizontal direction (Y direction). Each of the plurality of dummy gate structures DGS may have a structure in which an oxide layer D122, a dummy gate layer D124, and a capping layer D126 are sequentially stacked. In some embodiments, the dummy gate layer D124 may include polysilicon, and the capping layer D126 may include a silicon nitride layer.

Referring to FIG. 10A, after a plurality of first insulating spacers 118 covering both sidewalls of each of the plurality of dummy gate structures DGS are formed, portions of the plurality of sacrificial layers 104 and portions of a plurality of nanosheet layers NS (refer to FIG. 9) may be etched by using the plurality of dummy gate structures DGS and the plurality of first insulating spacers 118 as etching masks. As a result, the plurality of nanosheet layers NS may be divided into the plurality of nanosheet stacks NSS each including the plurality of nanosheet channel layers N1, N2, and N3. By using the etching process, a stacked pattern SP including the plurality of sacrificial layers 104 and the plurality of nanosheet channel layers N1, N2, and N3 may be formed.

By using the etching process, the plurality of active region recesses R1 and a plurality of source/drain spaces SDS exposing sidewalls of the stacked pattern SP may be formed. To form the plurality of active region recesses R1 and the plurality of source/drain spaces SDS, the etching process may be performed by using a dry etching process, a wet etching process, or a combination thereof.

Referring to FIG. 10B, each of a plurality of active region recesses R1 may further include a plurality of active region sidewall recesses R1_S. The plurality of active region sidewall recesses R1_S may be obtained by further removing portions of the sidewalls of the sacrificial layer 104 and the oxide layer 105 at a certain thickness with respect to the plurality of active region recesses R1. Because the plurality of nanosheet channel layers N1, N2, and N3 have not been removed during this process, end portions of the plurality of nanosheet channel layers N1, N2, and N3 may protrude from the sacrificial layer 104 and the oxide layer 105 due to the plurality of active region sidewall recesses R1_S.

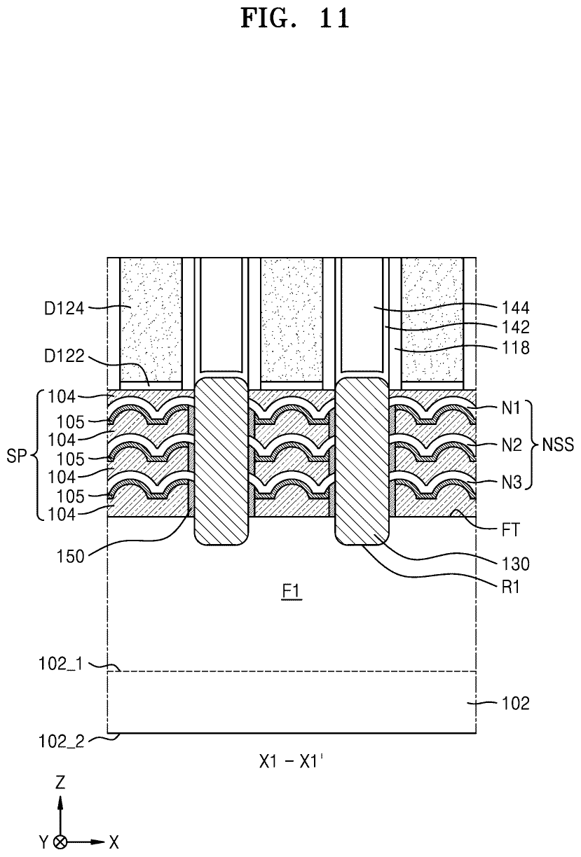

Referring to FIG. 11, the inner spacer 150 filling the plurality of active region sidewall recesses R1_S may be formed, and the plurality of source/drain regions 130 filling the plurality of active region recesses R1 may be formed.

In some embodiments, the inner spacer 150 may cover sidewalls in the first horizontal direction (X direction) of the plurality of sacrificial layers 104 and the oxide layer 105. A pair of inner spacers 150 may be formed to be apart from each other in the first horizontal direction (X direction) with the sacrificial layer 104 and the oxide layer 105 therebetween. In addition, each of the upper and lower surfaces of the inner spacer 150 may be in contact with the plurality of nanosheet channel layers N1, N2, and N3. In this case, the inner spacer 150 may include silicon nitride, silicon oxide, SiCN, SiBN, SiON, SiOCN, SiBCN, SiOC, or a combination thereof.

In some embodiments, to form the plurality of source/drain regions 130, a semiconductor material may be epitaxially grown from sidewalls of each of the plurality of nanosheet channel layers N1, N2, and N3 exposed at the plurality of active region recesses R1 and the surfaces of the plurality of active regions F1.

The insulating liner 142 may be deposited on the plurality of source/drain regions 130, after which the inter-gate insulating layer 144 may be formed on the insulating liner 142. Then, upper surfaces of a plurality of capping layers D126 (refer to FIG. 10A) may be exposed by etching respective portions of the insulating liner 142 and the inter-gate insulating layer 144. Thereafter, the capping layer D126 may be removed to expose the dummy gate layer D124, and the insulating liner 142 and the inter-gate insulating layer 144 may be partially removed so that an upper surface of the inter-gate insulating layer 144 and an upper surface of the dummy gate layer D124 are approximately on the same level.

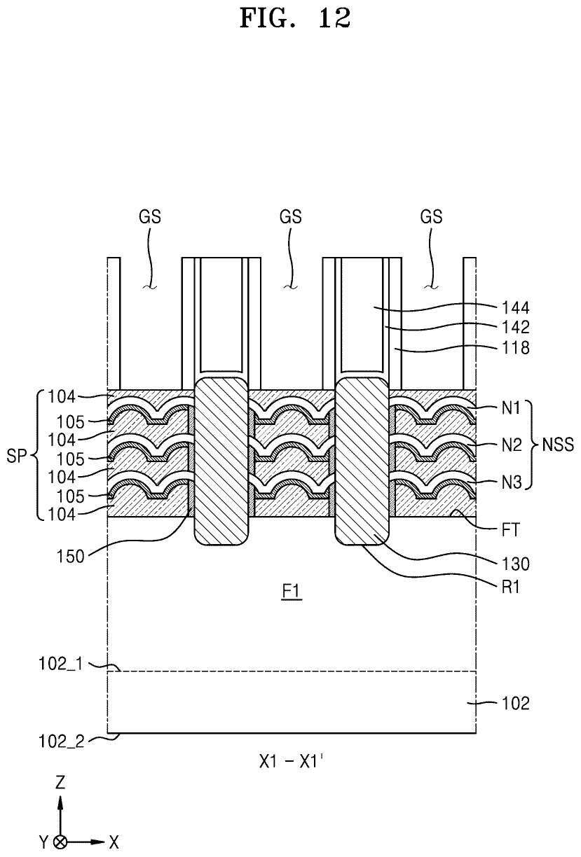

Referring to FIG. 12, a gate space GS may be provided by removing the dummy gate layer D124 and the dummy oxide layer D122 from the resultant product of FIG. 11.

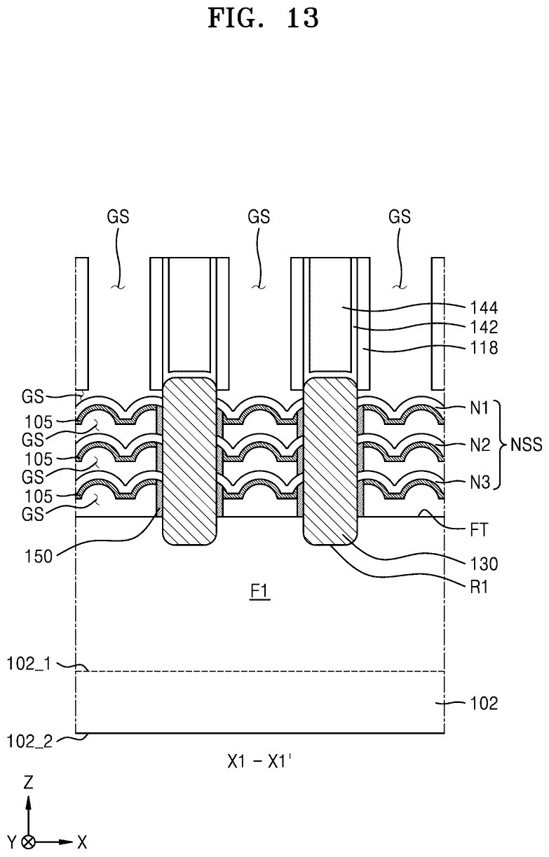

Referring to FIG. 13, by selectively removing the plurality of sacrificial layers 104 remaining on the substrate 102 by using the gate space GS from the resultant product of FIG. 12, the gate space GS may be extended to a space between each of the plurality of nanosheet channel layers N1, N2, and N3 and a space between the first nanosheet channel layer N1 and the fin upper surface FT.

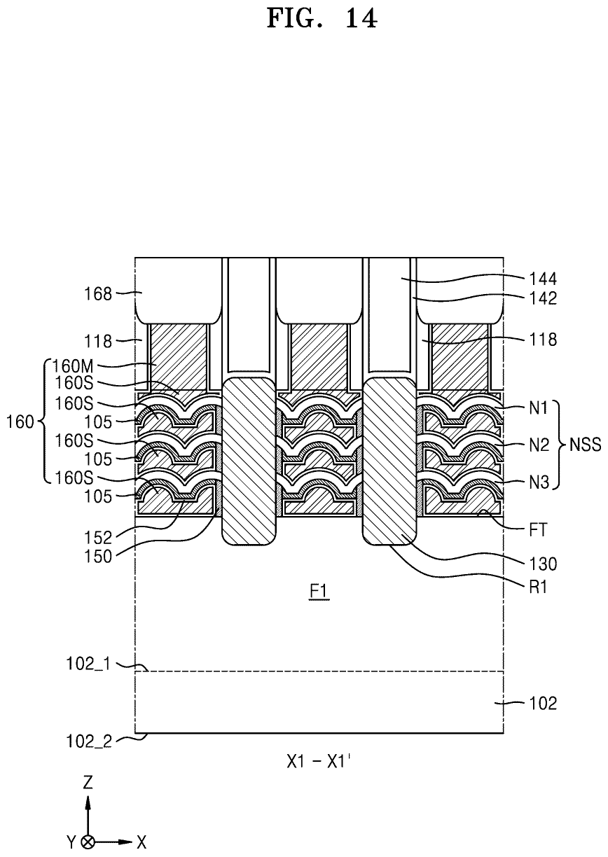

Referring to FIG. 14, the gate dielectric layer 152 covering exposed surfaces of each of the plurality of nanosheet channel layers N1, N2, and N3, the plurality of oxide layers 105, and the plurality of active regions F1 may be formed. An atomic layer deposition (ALD) process may be used to form the gate dielectric layer 152. Thereafter, the gate line 160 filling the gate space GS (refer to FIG. 13) may be formed on the gate dielectric layer 152. Thereafter, a portion of each of the gate line 160 and the first insulating spacer 118 may be removed from upper surfaces thereof to lower their respective heights, and a plurality of capping insulating patterns 168 covering the upper surfaces of each of the gate line 160 and the first insulating spacer 118 may be formed.

In some embodiments, the gate line 160 may include a metal, metal nitride, metal carbide, or a combination thereof. The ALD process or a chemical vapor deposition (CVD) process may be used for forming the gate line 160. The gate line 160 may be formed to be apart from the plurality of nanosheet channel layers N1, N2, and N3 and the plurality of oxide layers 105 with the gate dielectric layer 152 therebetween.

In some embodiments, each of the plurality of gate lines 160 may include the main gate 160M and the plurality of sub-gates 160S.

Referring to FIG. 2A again, a plurality of source/drain contact holes, which penetrate an insulating structure including the insulating liner 142 and the inter-gate insulating layer 144, and expose the plurality of source/drain regions 130, may be formed. Through the source/drain contact holes, a certain region of the plurality of source/drain regions 130 may be removed using an anisotropic etching process, and accordingly, the plurality of source/drain contact holes may extend further toward the substrate 102.

Thereafter, a portion of the source/drain region 130 exposed by the plurality of source/drain contact holes may be processed, and accordingly, the metal silicide layer 172 may be formed. In some embodiments, to form the metal silicide layer 172, a metal liner conformally covering the exposed surface of the source/drain region 130 may be formed, and a process of inducing a reaction between the source/drain region 130 and a metal constituting the metal liner by applying heat treatment, may be included. After the metal silicide layer 172 is formed, a remaining portion of the metal liner may be removed. In some embodiments, when the metal silicide layer 172 includes Ti silicide, the metal liner may include a Ti layer. The source/drain contact CA including the conductive barrier layer 174 and the contact plug 176 may be formed on the metal silicide layer 172.

Thereafter, the upper insulating structure 180 may be formed by sequentially forming the etching stop layer 182 and the interlayer insulating layer 184 covering the upper surface of each of the inter-gate insulating layer 144, the plurality of source/drain contacts CA, and the plurality of capping insulating patterns 168, and the plurality of source/drain via contacts VA penetrating the upper insulating structure 180 in the vertical direction (Z direction) and respectively connected to the plurality of source/drain contacts CA may be formed.

Thereafter, the upper insulating layer 192 covering the upper surface of each of the upper insulating structure 180 and the plurality of source/drain via contacts VA may be formed, and the plurality of upper wiring layers M1 penetrating the upper insulating layer 192 in the vertical direction (Z direction) and respectively connected to the plurality of source/drain via contacts VA may be formed.

The integrated circuit device 100 of FIGS. 1 and 2A through 2C may be manufactured using the processes described above.

In the integrated circuit device 100 according to the disclosure, the sacrificial layer 104 having a curved upper surface may be arranged on the substrate 102 to induce local strain. In this case, for example, in the sacrificial layer 104, an overall curve-shaped upper surface may be formed by growing a plurality of nano-crystal grains apart from each other, and the curvature may be adjusted by controlling the size and/or density of the nano-crystal grain. Next, the plurality of nanosheet channel layers N1, N2, and N3 including the TMD material may be sequentially formed between the plurality of sacrificial layers 104. Before forming each of the plurality of nanosheet channel layers N1, N2, and N3 on the sacrificial layer 104, the oxide layer 105 may be formed on the upper surface of the sacrificial layer 104, and the oxide layer 105 may support each of the plurality of nanosheet channel layers N1, N2, and N3 and may also function as a gate dielectric with the gate dielectric layer 152. Because the integrated circuit device 100 according to the disclosure has a curved channel layer as a result of the processes described above, the electrical characteristics of the integrated circuit device 100 may be improved, and because a gate insulating material may not be deposited in the inner spacer 150, the parasitic capacitance of the integrated circuit device 100 may be reduced.

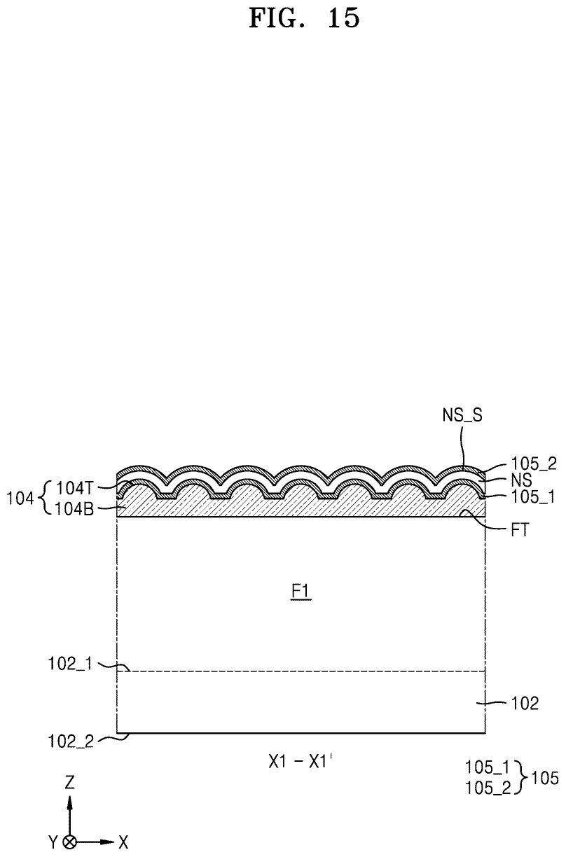

FIGS. 15 through 17 are cross-sectional views illustrating a method of manufacturing the integrated circuit device 100a, according to embodiments, and FIG. 18 is a cross-sectional view of the integrated circuit device 100a taken along line X1-X1′ in FIG. 1. It will be understood that the integrated circuit device 100a of FIGS. 15 through 18 is not mutually exclusive with the integrated circuit device 100 described with reference to FIGS. 1, 2A-2B, 3-9, 10A-10B, and 11 through 14, and components having the same reference numerals may be the same. Hereinafter, duplicate descriptions of the same components are omitted, and differences from the descriptions of the integrated circuit device 100 given with reference to FIGS. 1, 2A-2B, 3-9, 10A-10B, and 11 through 14 are described.

Referring to FIG. 15, the sacrificial layer 104 may be formed on the fin upper surface FT of the active region F1 of the substrate 102, and the first oxide layer 105_1, the nanosheet layer NS, and the second oxide layer 105_2 may be sequentially formed on the sacrificial layer 104.

In some embodiments, the sacrificial layer 104 may include the bottom unit 104B and the upper surface unit 104T, and the nanosheet layer NS may include the TMD material. The oxide layer 105 may include the first oxide layer 105_1 and the second oxide layer 105_2. The first oxide layer 105_1 and the second oxide layer 105_2 may include substantially the same material. In some embodiments, the first oxide layer 105_1 and the second oxide layer 105_2 may have the same thickness, but this is only an example, and the first oxide layer 105_1 and the second oxide layer 105_2 may also have different thicknesses.

A process of forming the sacrificial layer 104 and the nanosheet layer NS may be the same as the processes described with reference to FIGS. 3 and 5, respectively. A process of forming the first oxide layer 105_1 may be the same as that described with reference to FIG. 4, and a process of forming the second oxide layer 105_2 may be the same as the process of forming the first oxide layer 105_1.

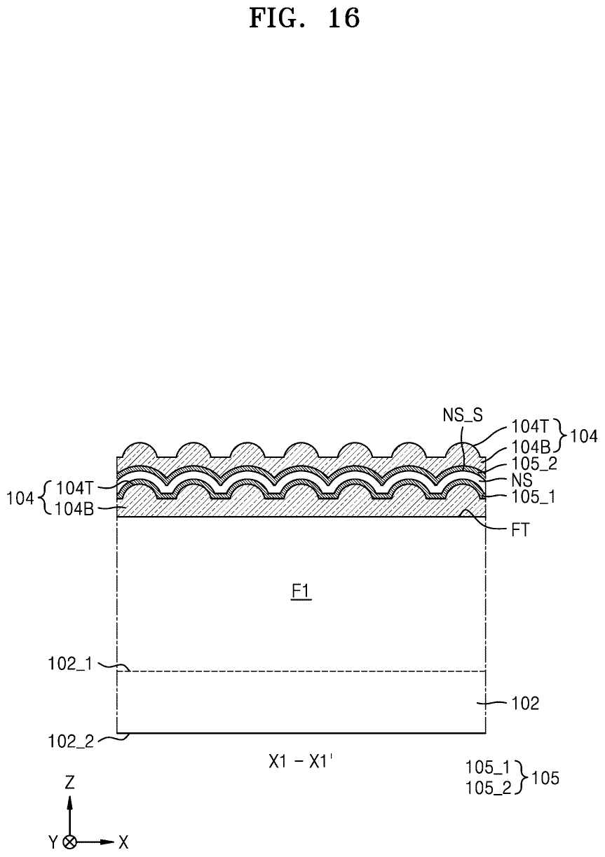

Referring to FIG. 16, the sacrificial layer 104 may be formed on the resultant product of FIG. 15. The process described with reference to FIG. 16 may be the same as that described with reference to FIG. 7, except that the nanosheet layer NS may be formed on the second oxide layer 105_2 instead of directly on the sacrificial layer 104.

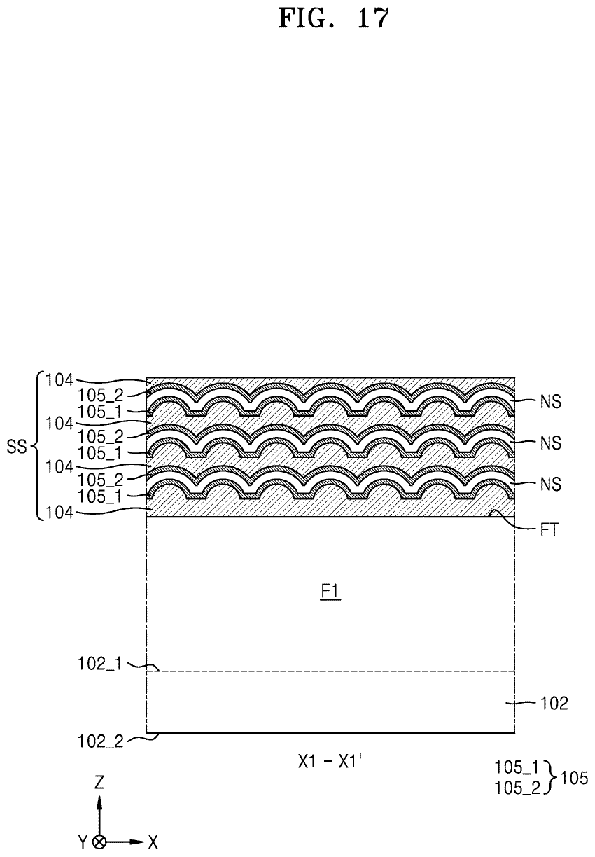

Referring to FIG. 17, the stacked structure SS may be formed so that the sacrificial layer 104, the first oxide layer 105_1, the nanosheet layer NS, and the second oxide layer 105_2 are alternately stacked one by one on the substrate 102. The stacked structure SS may be formed by repeatedly performing the processes described with reference to FIGS. 15 and 16. In FIG. 17, three of the nanosheet layers NS are included in the stacked structure SS, but this is only an example, and does not limit the disclosure.

Next, after the same processes described with reference to FIGS. 9, 10A, 11, 12, 13, and 14 are performed, by sequentially forming the metal silicide layer 172, the plurality of source/drain contacts CA including the conductive barrier layer 174 and the contact plug 176, the upper insulating structure 180 including the etching stop layer 182 and the interlayer insulating layer 184, the plurality of source/drain via contacts VA, the upper insulating layer 192, and the upper wiring layer M1, the integrated circuit device 100a of FIG. 18 may be formed.

In the integrated circuit device 100a of FIG. 18, unlike the integrated circuit device 100 of FIG. 2A, because the first oxide layer 105_1 is formed on upper portions of the plurality of nanosheet channel layers N1, N2, and N3, and the second oxide layer 105_2 is formed under lower portions of the plurality of nanosheet channel layers N1, N2, and N3, in the processes described with reference to FIGS. 10A and 10B, while the sacrificial layer 104 is removed from the plurality of active region sidewall recesses R1_S at a certain thickness, both portions of the first oxide layer 105_1 and the second oxide layer 105_2 may also be removed at a certain thickness together with the sacrificial layer 104.

Referring to FIG. 18 again, because the first and second oxide layers 105_1 and 105_2 may also be used as gate dielectric layers together with the gate dielectric layer 152, the gate dielectric layer 152 may surround the sub-gate 160S because both an upper portion and a lower portion of the sub-gate 160S may be covered by the first and second oxide layers 105_1 and 1-5_2. However, in some other embodiments, the gate dielectric layer 152 surrounding the sub-gate 160S may be omitted.

As described above with reference to the integrated circuit device 100, the integrated circuit device 100a according to the disclosure may deposit the sacrificial layer 104 having a curved upper surface on the substrate 102 to induce the local strain. In this case, for example, in the sacrificial layer 104, an overall curve-shaped upper surface may be formed by growing a plurality of nano-crystal grains apart from each other, and the curvature may be adjusted by controlling the size and/or density of the nano-crystal grain. Next, the plurality of nanosheet channel layers N1, N2, and N3 including the TMD material may be sequentially formed between the plurality of sacrificial layers 104. Before each of the plurality of nanosheet channel layers N1, N2, and N3 is formed on the sacrificial layer 104, the first oxide layer 105_1 may be formed on the upper surface of the sacrificial layer 104, and after each of the plurality of nanosheet channel layers N1, N2, and N3 is formed, the second oxide layer 105_2 may be formed on the upper surface of the plurality of nanosheet channel layers N1, N2, and N3. The oxide layer 105 may support each of the plurality of nanosheet channel layers N1, N2, and N3, and may also function as a gate dielectric together with the gate dielectric layer 152. Because the integrated circuit device 100a according to the disclosure has a curved channel layer as a result of the processes described above, the electrical characteristics of the integrated circuit device 100a may be improved, and because a gate insulating material is not deposited in the inner spacer 150, the parasitic capacitance of the integrated circuit device 100a may be reduced.

As described above, embodiments have been disclosed in the drawings and the disclosure. While the embodiments have been described herein with reference to specific terms, it should be understood that they have been used only for the purpose of describing the disclosure and not for limiting the scope of the disclosure as defined in the claims. Thus, those with ordinary skill in the art will appreciate that various modifications and equivalent embodiments are possible without departing from the scope of the disclosure. Accordingly, the true scope of protection of the disclosure should be determined by the following claims.

What is claimed is:

1. An integrated circuit device comprising:
an active region extending in a first horizontal direction on a substrate;
a plurality of channel layers apart from each other on the active region in a vertical direction, and extending in the first horizontal direction;
oxide layers under the plurality of channel layers, respectively;
a gate line extending on the active region in a second horizontal direction crossing the first horizontal direction, and surrounding the plurality of channel layers and the oxide layers;
a source/drain region on the active region and in contact with the plurality of channel layers; and
an inner spacer, wherein the inner spacer comprises:
one sidewall in contact with a sidewall of the source/drain region;
another sidewall opposite the one sidewall and on a sidewall of the gate line; and
an upper surface and a lower surface, each in contact with the plurality of channel layers,
wherein the plurality of channel layers comprise a transition metal dichalcogenide (TMD) compound, and
wherein each of the plurality of channel layers comprises a plurality of convex curved units in the vertical direction.

2. The integrated circuit device of claim 1, wherein a thickness of each of the plurality of channel layers is in a range of about 0.6 nm to about 3 nm.

3. The integrated circuit device of claim 1, wherein the oxide layers are apart from the source/drain region with the inner spacer therebetween in the second horizontal direction.

4. The integrated circuit device of claim 1, wherein the gate line comprises:
a sub-gate between adjacent ones of the plurality of channel layers in the vertical direction, and between a lowermost channel layer of the plurality of channel layers and the active region,
wherein the sub-gate surrounds upper surfaces of the plurality of channel layers, side surfaces of the plurality of channel layers and the oxide layers, and lower surfaces of the oxide layers.

5. The integrated circuit device of claim 1, further comprising:
a gate dielectric layer on a sidewall of the gate line, and surfaces of the plurality of channel layers and the oxide layers.

6. The integrated circuit device of claim 1, wherein at least two of the plurality of convex curved units comprise substantially identical curvatures.

7. The integrated circuit device of claim 1, wherein at least two of the plurality of convex curved units comprise different curvatures.

8. The integrated circuit device of claim 1, wherein a width of the plurality of channel layers extending in the first horizontal direction is greater than a width of each of the oxide layers in the first horizontal direction.

9. The integrated circuit device of claim 1, wherein a curved pattern of an upper surface of the plurality of channel layers corresponds to a curved pattern of a lower surface of the plurality of channel layers.

10. The integrated circuit device of claim 1, wherein lower surfaces of the plurality of channel layers are coplanar with upper surfaces of the oxide layers.

11. An integrated circuit device comprising:
an active region extending in a first horizontal direction on a substrate;
a plurality of channel layers apart from each other on the active region in a vertical direction, and extending in the first horizontal direction;
a first oxide layer and a second oxide layer apart from each other, the plurality of channel layers therebetween;
a gate line extending on the active region in a second horizontal direction crossing the first horizontal direction, and surrounding the plurality of channel layers, the first oxide layer, and the second oxide layer;
a source/drain region on the active region and in contact with the plurality of channel layers; and
an inner spacer comprising:
one sidewall in contact with a sidewall of the source/drain region;
another sidewall opposite the one sidewall and covering a sidewall of the gate line; and
an upper surface and a lower surface, each in contact with the plurality of channel layers,
wherein the plurality of channel layers comprise a transition metal dichalcogenide (TMD) compound, and
wherein each of the plurality of channel layers comprises a plurality of convex curved units in the vertical direction.

12. The integrated circuit device of claim 11, wherein the first oxide layer is under the plurality of channel layers, and the second oxide layer is on the plurality of channel layers.

13. The integrated circuit device of claim 11, wherein an upper surface of the first oxide layer is coplanar with lower surfaces of the plurality of channel layers, and a lower surface of the second oxide layer is coplanar with upper surfaces of the plurality of channel layers.

14. The integrated circuit device of claim 11, wherein the gate line comprises:
a sub-gate between adjacent ones of the plurality of channel layers in the vertical direction, and between a lowermost channel layer of the plurality of channel layers and the active region, and
wherein the sub-gate surrounds an upper surface of the second oxide layer, side surfaces of the plurality of channel layers and the first and second oxide layers, and a lower surface of the first oxide layer.

15. The integrated circuit device of claim 11, wherein a thickness of each of the plurality of channel layers is in a range of about 0.6 nm to about 3 nm.

16. The integrated circuit device of claim 11, wherein a width of the plurality of channel layers extending in the first horizontal direction is greater than a width of the first oxide layer in the first horizontal direction.

17. The integrated circuit device of claim 11, wherein a curved pattern of an upper surface of the plurality of channel layers corresponds to a curved pattern of a lower surface of the plurality of channel layers.

18. An integrated circuit device comprising:
an active region extending in a first horizontal direction on a substrate;
a nanosheet stack comprising a plurality of nanosheets apart from an upper surface of the active region in a vertical direction;
a gate line extending on the active region in a second horizontal direction crossing the first horizontal direction, and surrounding the plurality of nanosheets, the gate line comprising a sub-gate between adjacent ones of the plurality of nanosheets in the vertical direction and between a lowermost nanosheet of the plurality of nanosheets and the active region, and on an uppermost nanosheet of the plurality of nanosheets;
a source/drain region in contact with the plurality of nanosheets;
an insulating spacer on sidewalls of the gate line;
an inner spacer between the sub-gate and the source/drain region; and
a first oxide layer between lower surfaces of the plurality of nanosheets and the gate line,
wherein the inner spacer is between the first oxide layer and the source/drain region, and
wherein the plurality of nanosheets comprise a transition metal dichalcogenide (TMD) compound, and upper surfaces and lower surfaces of the plurality of nanosheets comprise a plurality of convex uneven units in the vertical direction.

19. The integrated circuit device of claim 18, further comprising a second oxide layer between the upper surfaces of the plurality of nanosheets and the gate line.

20. The integrated circuit device of claim 18, wherein a thickness of each of the plurality of nanosheets is in a range of about 0.6 nm to about 3 nm.
